(19) United States
(12) Patent Application Publication
(10) Pub. No.: US 2020/0296860 A1
(43) Pub. Date: Sep. 17, 2020

(54) HYBRID LIQUID COOLING AND AIR COOLING OF STORAGE ENCLOSURES

(71) Applicant: Seagate Technology LLC, Cupertino, CA (US)

(72) Inventor: Lon Matthew Stevens, Longmont, CO (US)

(21) Appl. No.: 16/299,305

(22) Filed: Mar. 12, 2019

(51) Int. Cl. H05K 7/20; H05K 7/14

(52) U.S. Cl. CPC H05K 7/20572; H05K 7/20736; H05K 7/20609; H05K 7/1488

(57) ABSTRACT

An apparatus includes an enclosure with a first data storage section, a second data storage section, a first cooling section positioned therebetween, and a second cooling section. The apparatus also includes an air-to-liquid heat exchanger positioned in the first cooling section and configured to cool air directed from the first data storage section towards the second data storage section and the second cooling section.

### SUMMARY

In certain embodiments, an apparatus includes an enclosure with a first data storage section, a second data storage section, a first cooling section positioned therebetween, and a second cooling section. The apparatus also includes an air-to-liquid heat exchanger positioned in the first cooling section and configured to cool air directed from the first data storage section towards the second data storage section and the second cooling section.

In certain embodiments, a system includes a data storage system having an enclosure with a first data storage section, a second data storage section, a first cooling section positioned therebetween, and fan modules positioned within a second cooling section. The system also includes a cooling system with a pump and a heat exchanger fluidly coupled to each other. The heat exchanger is positioned within the first cooling section of the enclosure and is arranged to cool air directed towards the fan modules.

In certain embodiments, a method is disclosed for cooling data storage devices in an enclosure with a first data storage section, a second data storage section, a first cooling section positioned therebetween, and a second cooling section. The method includes powering fan modules positioned in the second cooling section to draw air across the first data storage section, the first cooling section, and the second data storage section. The method also includes pumping liquid through a heat exchanger positioned within the first cooling section to cool air passing through the first cooling section and the second data storage section.

While multiple embodiments are disclosed, still other embodiments of the present invention will become apparent to those skilled in the art from the following detailed description, which shows and describes illustrative embodiments of the invention. Accordingly, the drawings and detailed description are to be regarded as illustrative in nature and not restrictive.

### BRIEF DESCRIPTION OF THE DRAWINGS

FIG. 1 shows a perspective view of a data storage system, in accordance with certain embodiments of the present disclosure.

FIG. 2 shows a partially exploded, perspective view of an enclosure, in accordance with certain embodiments of the present disclosure.

FIG. 3 shows a top view of the enclosure of FIG. 2 with storage devices positioned therein, in accordance with certain embodiments of the present disclosure.

FIG. 3A shows a schematic top view of the enclosure of FIG. 2 with storage devices positioned therein, in accordance with certain embodiments of the present disclosure.

FIG. 4 shows a partially exploded, perspective view of a back end of the enclosure of FIGS. 2 and 3, in accordance with certain embodiments of the present disclosure.

FIG. 5 shows a schematic of a cooling system, in accordance with certain embodiments of the present disclosure.

FIG. 6 shows a heat exchanger, in accordance with certain embodiments of the present disclosure.

While the disclosure is amenable to various modifications and alternative forms, specific embodiments have been shown by way of example in the drawings and are described in detail below. The intention, however, is not to limit the disclosure to the particular embodiments described but instead is intended to cover all modifications, equivalents, and alternatives falling within the scope the appended claims.

### DETAILED DESCRIPTION

Data storage systems are used to store and/or process vast amounts of data. It can be challenging to keep the systems within a desired temperature range because of the amount of heat the systems typically generate during operation. Data storage systems can include cooling devices such as air movers (e.g., fans) that assist with maintaining the systems within the desired temperature range. However, as data storage systems continue to increase in density and/or power consumption, air-based cooling (e.g., cooling using fan modules) by itself may not provide enough cooling. Other cooling approaches such as liquid-only based cooling (e.g., liquid cooling plates, liquid immersion) can provide comparatively better cooling but data storage systems incorporating liquid-based cooling are heavy, expensive, and/or difficult to service. Certain embodiments of the present disclosure feature systems, methods, and devices involving hybrid air-based cooling and liquid-based cooling approaches for data storage systems.

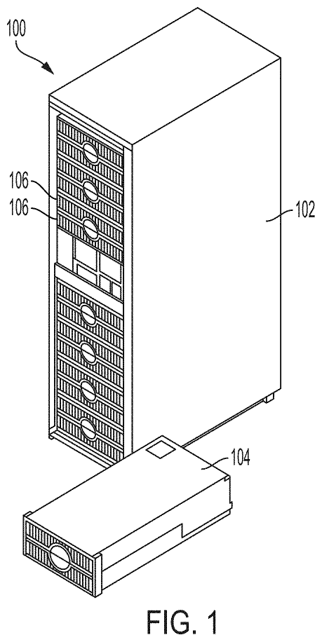

FIG. 1 shows a data storage system 100 including a rack 102 (e.g., a cabinet) with a plurality of enclosures 104. Each enclosure 104 can include multiple drawers or storage levels 106 that house data storage devices and/or data processing devices (e.g., data processing units such as graphics processing units) installed within the drawers or storage levels 106. Each enclosure 104 itself can be arranged in a drawer-like fashion to slide into and out of the rack 102, although the enclosures 104 are not necessarily arranged as such.

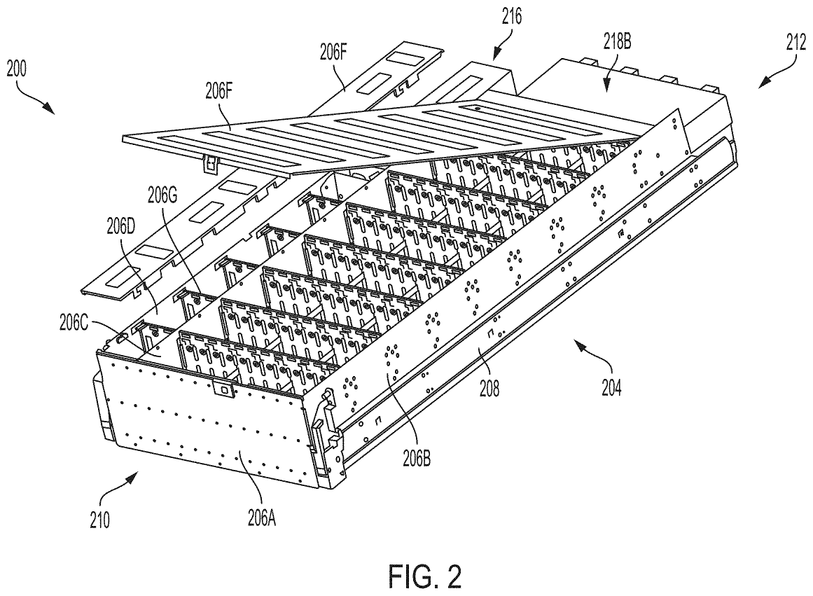

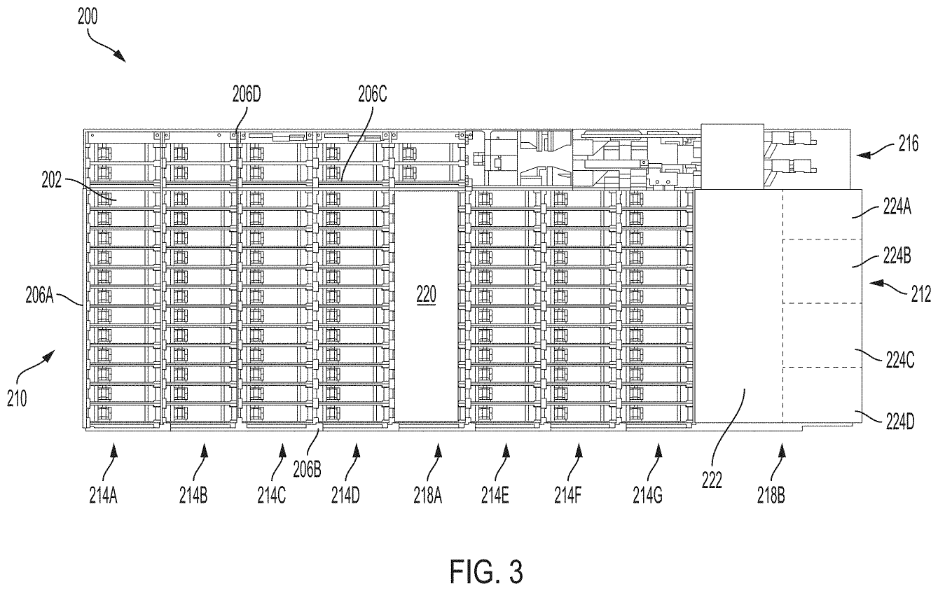

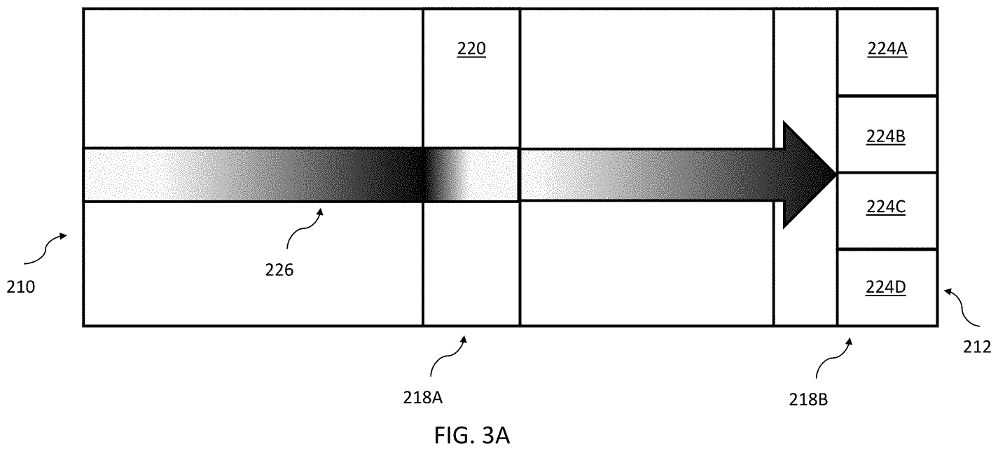

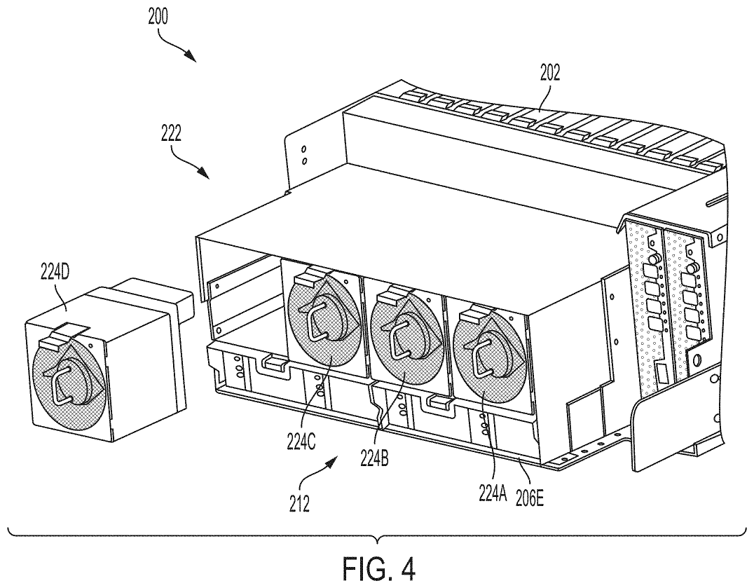

FIG. 2 shows a partially exploded view of an enclosure 200, which can be utilized in a data storage system such as the data storage system 100 of FIG. 1. For example, a rack such as the rack 102 in FIG. 1 can include multiple individual enclosures such as the enclosure 200. FIG. 3 shows a top view of the enclosure 200 with data storage devices 202 positioned within the enclosure 200, and FIG. 4 shows a back end of the enclosure 200.

The enclosure 200 includes a chassis 204 with a front side wall 206A, first side wall 206B, a second side wall 206C, a third side wall 206D, a bottom wall 206E (shown FIG. 4), multiple top covers 206F, and multiple laterally-extending interior walls 206G that extend between the various side walls. The enclosure 200 may include slides 208 coupled to the chassis 204 that enable the enclosure 200 to move into and out of a rack.

The enclosure 200 extends between a front end 210 and a back end 212. When assembled, the enclosure 200 houses and supports the data storage devices 202 (e.g., hard disc drives and/or solid state drives), data processing units (e.g., graphic processing units), electrical components (e.g., wiring, circuit boards), and cooling devices (e.g., air movers, heat exchangers). The enclosure 200 can be split into one or more data storage areas 214A-G, electrical component areas 216, and cooling areas (e.g., a first cooling area 218A and a second cooling area 218B). In addition to, or in replace of, data storage, the data storage areas 214A-G can be used for data processing.

FIG. 3 shows seven rows of separate data storage areas 214A-G extending between the front side wall 206A and the second side wall 206C. The first data storage area 214A near the front end 210 of the chassis 204 extends between the front side wall 206A and one of the interior walls 206G, and the rest of the data storage areas 214B-G extend between two of the interior walls 206G. Each data storage device 202 can be removably coupled between the front side wall 206A and one of the interior walls 206G in the first data storage area 214A or between two of the interior walls 206G in the other data storage areas 214B-G. The data storage areas 214A-G can include data processing units in addition to or in replace of data storage devices. For example, the data storage areas 214A-G could include a plurality of graphics processing units programmed to mine cryptocurrencies or perform other data-intensive operations. The enclosure 200 is shown as including one electrical component area 216 where various electrical controllers, printed circuit boards, etc., are positioned. Electrical components can be positioned in other areas of the enclosure 200 too.

The enclosure 200 is also shown as including the first cooling area 218A that is positioned between two of the data storage areas 214D and 214E. As will be described in more detail below, a heat exchanger 220 can be positioned within the first cooling area 218A to help cool portions of the enclosure 200 and its components.

The second cooling area 218B extends between the back end 212 of the enclosure 200 and the data storage area 214G. The second cooling area 218B includes a cooling plenum 222 with several cooling devices 224A-D (e.g., air-movers such as fans) positioned within the cooling plenum 222. The enclosure 200 may include multiple cooling plenums where, for example, each cooling device 224A-D is associated with its own cooling plenum. In another example, two or more cooling devices may share a cooling plenum. In certain embodiments, the cooling plenum 222 does not include or otherwise house data storage devices 202. Although not shown in the Figures, some of the chassis walls may form the plenum walls. For example, a single wall may form both the chassis side wall and plenum side wall (e.g., a single wall formed by one piece of sheet metal or formed by the same two pieces of sheet metal). The plenum walls and the chassis walls can be made of metal (e.g., aluminum or steel sheets of metal), plastic, etc.

The cooling devices 224A-D shown in FIG. 4 are fan modules with blades that rotate around a rotation axis. The fan modules 224A-D draw air from the front end 210 of the enclosure 200 towards the back end 212 of the enclosure 200 and then move the air out of the enclosure 200. The air cools the data storage devices 202, which generate heat during their operation. As enclosures are more densely packed with data storage devices, enclosures require more cooling to maintain desired operating temperatures for the data storage devices. For example, as air passes across each data storage area 214B-G, the air may increase in temperature by a few degrees Celsius (e.g., 2 or 3 degrees Celsius). With seven data storage areas and assuming 2- or 3-degree temperature increases for each data storage area, the air passing through the enclosure 200 may have increased by 14 to 21 degrees Celsius from an initial ambient temperature by the time the air reaches the last of the data storage areas 214G. As such, hard disk drives may reach or exceed their upper operating temperature when positioned in a densely-packed enclosure within in an environment with a high initial ambient air temperature.

One approach for addressing increased cooling needs is to increase the speed at which the fan modules' blades rotate (e.g., increased operating speeds result in smaller air temperature increases across the enclosure). However, rotating the blades of the fan modules 224A-D generates acoustic energy (e.g., energy transmitted through air) and chassis vibration (e.g., energy transmitted through the chassis 204 itself)—both of which can affect the performance of the data storage devices 202 and both of which can increase in amplitude with increased rotational speeds. Further, increased rotational speeds increases the amount of power consumed by the fan modules. When acoustic energy or chassis vibration is transmitted to the data storage devices 202 in the enclosure 200, the data storage devices 202 vibrate, which affects the data storage devices' 202 ability to write data and read data. For data storage devices 202 that are hard disk drives, the vibration resulting from acoustic energy and chassis vibration can make it difficult for the read/write heads in the hard disk drives to settle on or follow a desired data track during data reading and data writing operations. The risk of acoustic energy affecting performance increases as hard disk drives store more data per disk and therefore require finer positioning of the read/write heads.

Incorporating the heat exchanger 220 into the enclosure 200 can provide better cooling compared to air-only cooling approaches. With the addition of the heat exchanger 220, the operating speed of the fan modules 224A-D (and therefore the amount of acoustic energy generated) can be reduced while still accomplishing similar or better cooling. As shown in FIGS. 3 and 3A, the heat exchanger 220 can be positioned between data storage areas in the enclosure 200, for example, near a middle portion of the enclosure 200. Although the heat exchanger 220 is shown as extending between the first side wall 206B and the second side wall 206C, the heat exchanger 220 can extend any distance between the first side wall 206B and the third side wall 206D. Further, although only one heat exchanger 220 is shown in FIGS. 3 and 3A, the enclosure 200 can include multiple heat exchangers and at various positioned within the enclosure 200.

The heat exchanger 220 may be a liquid-to-air heat exchanger. Liquid-to-air heat exchangers include one or more hollow tubes through which a liquid (e.g., water) is passed through. The heat exchanger 220 may include fins or plates conductively coupled to the tubes such that the fins or plates are cooled by the water (e.g., cooler water) passing through the tubes.

FIG. 3A includes an arrow 226 that represents air passing through the enclosure 200. The shading in the arrow represents the temperature of the air as the air passes through the enclosure 200. Darker shading represents higher temperatures. The air 226 (at an ambient temperature) enters the enclosure 200 at the front end 210 of the enclosure 200. As the air 226 passes over components (e.g., data storage devices 202, data processing units), the temperature of the air 226 increases. The air 226 passing through the heat exchanger 220 is cooled by the tube-fin configuration via convection such that components (e.g., data storage devices 202, data processing units) downstream of the heat exchanger 220 are cooled by the cooler air. As the air 226 passes over the components downstream of the heat exchanger 220, the temperature of the air 226 increases. The air 226 is pulled out of the back end 212 of the enclosure 200 by the fan modules 224A-D. In certain embodiments, the components with lower upper operating temperatures (e.g., components with greater need for heat mitigation) are positioned downstream and closest to the hear exchanger 220 than components designed to operate at higher temperatures.

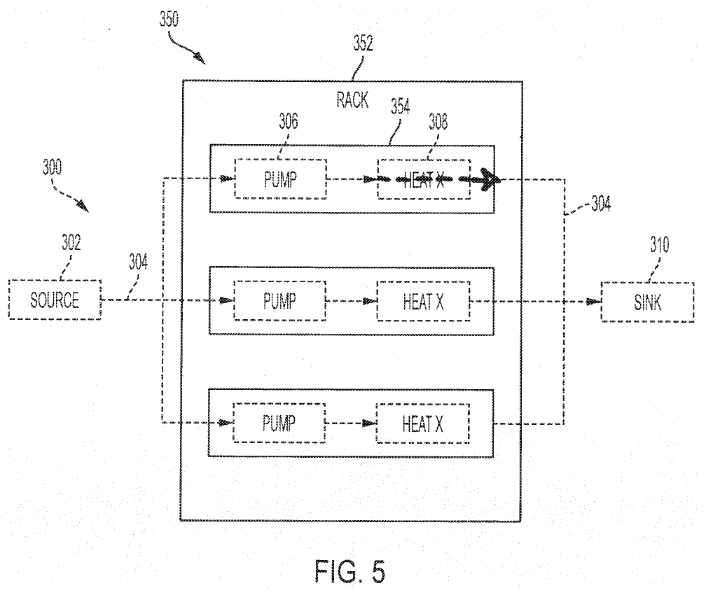

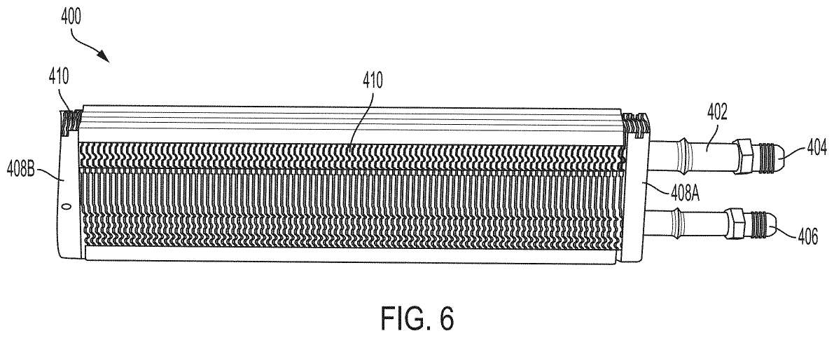

Below, various aspects of a cooling system 300 shown in FIG. 5 (including a heat exchanger such as the heat exchanger 220) are described. FIG. 6 shows one example of a heat exchanger 400 (such as the heat exchanger 220) that can be incorporated into the enclosure 200 and the cooling system 300.

FIG. 5 shows a schematic of the cooling system 300 including a liquid source 302 (e.g., a water reservoir), conduit 304 (e.g., piping), pumps 306 (e.g., water pumps), heat exchangers 308 (e.g., liquid-to-air heat exchangers), and a sink 310. The components of the cooling system 300 are outlined with dashed lines in FIG. 5. Although not shown in FIG. 5, various couplings (e.g., water-tight couplings) and manifolds between the source 302 and the sink 310 can be included as part of the cooling system 300.

In certain embodiments, the source 302 for the cooling system 300 is shared with a data center's water source (e.g., a connection to a public water utility). In other embodiments, the source 302 is a water reservoir that is cooled to provide water at a lower temperature (e.g., 10-15 degrees Celsius) than the temperature (e.g., 20-25 degrees Celsius) of water provided by the data center's water source. The conduit 304 is fluidly coupled to the source 302 and can include piping through which the water flows. In certain embodiments, some of the conduit 304 is flexible piping. For example, some of the conduit 304 may be positioned within a data storage system 350 and need to be flexible so that drawers or enclosures within the data storage system 350 can be moved or otherwise accessed for maintenance.

FIG. 5 shows the data storage system 350 (such as the data storage system 100 of FIG. 1) coupled to the cooling system 300. The data storage system 350 can include a rack 352 and enclosures 354 (such as the enclosure 104 of FIG. 1 and the enclosure 200 of FIGS. 2-4) positioned in the rack 352. One or more of the enclosures 354 includes one or more of the heat exchangers 308 of the cooling system 300. Water can be pumped via the pumps 306 from the source 302 through the conduit 304 to the heat exchangers 308 that are positioned in the enclosures 354. In certain embodiments, one or more pumps 306 are positioned in the enclosures 354. For example, each enclosure 354 containing one of the heat exchangers 308 can include one of the pumps 306. In embodiments, one or more of the pumps 306 can be positioned outside the enclosure and fluidly coupled at other points within the cooling system 300. After the water enters and exits the heat exchangers 308, the water is dispelled into the sink 310.

As the water passes through the heat exchangers 308, fins or plates of the heat exchangers 308 are cooled. The air in the enclosures 354 that flows past the heat exchangers 308 is also cooled. For example, the temperature of such air may be cooled by several degrees Celsius (e.g., 4-6, 2-20 degrees Celsius). As such, the air flowing between the heat exchangers and fan modules in the enclosures is at a colder temperature than what the air temperature would have been without the heat exchangers 308. Data storage devices within that area of the enclosure can operate within a lower-temperature environment.

In certain embodiments, the water is pumped at a consistent and predetermined flow rate through the heat exchangers 308. In other embodiments, the flow rate of the water is variable and/or intermittent. For example, to save energy costs, the pumps 306 can be turned off or operated for a lower flow rate when less cooling is required within the enclosures 354. The amount of cooling required at a given point in time can be determined based at least in part on one or more air-temperature measurements taken (e.g., via temperature sensors such as thermocouples) within the data storage system 350. Similarly, the operating speed of fan modules can be modified in response to air-temperature measurements. For example, if less cooling is required, the fan modules can be operated at a lower speed to reduce power consumption and/or to reduce the amount of acoustic energy generated by the fan modules.

In certain embodiments, the heat exchangers 308 are single-pass heat exchangers. With this type of heat exchanger, the water enters a tube on one side of the heat exchanger 308 and exits the tube on the opposite side of the heat exchanger 308. In other embodiments, the heat exchangers 308 are double-pass heat exchangers. With this arrangement, the water enters and exits a tube on the same side of the heat exchanger 308. The tube is U-shaped such that the water flows back-and-forth to and from one side of the heat exchanger. Double-pass heat exchangers may provide more uniform cooling compared to single-pass heat exchangers. For example, in a single-pass configuration, the water near the entrance of the heat exchanger will consistently be cooler than the water near the exit of the heat exchanger. As such, the temperature of the air passing through a single-pass heat exchanger will be cooler on the input side of the heat exchanger 308 compared to the temperature of the air on the output side of the heat exchanger 308. In certain embodiments, the heat exchangers 308 include tubes that are shaped to provide more than two passes of the water across the heat exchangers 308.

FIG. 6 shows one type of heat exchanger 400 that can be incorporated into the enclosures 200 and 354. The heat exchanger 400 shown in FIG. 6 is a double-pass heat exchanger. The heat exchanger 400 includes a tube 402 with an inlet 404 and an outlet 406. The tube 402 is U-shaped and extends from an entrance/exit side 408A of the heat exchanger 400 towards the opposite side 408B and back to the entrance/exit side 408A. For a double-pass heat exchanger, the entrance/exit side 408A can be positioned another side of the heat exchanger 400 than shown in FIG. 6 for easier installation and/or access for maintenance.

The heat exchanger 400 includes plates or fins 410 that are coupled to portions of the tube 402. The fins or plates 410 can be thin or oriented such that air can pass through gaps between each of the fins or plates 410. For example, the fins or plates 410 can be planar and rectangular shaped and oriented such that the fins or plates 410 extend lengthwise along a longitunidal axis of an enclosure. The fins or plates 410 can comprise thermally-conductive metals such as copper and aluminum. Increasing the number of fins or plates 410 in the heat exchanger 400 can increase the amount cooling provided by the heat exchanger 400 but also increases how much the heat exchanger 400 impedes the flow of air. For example, a higher number of fins or plates 410 in the heat exchanger 400 may result in smaller gaps between the fins or plates 410, which lets less air pass through the heat exchanger 400.

Various modifications and additions can be made to the embodiments disclosed without departing from the scope of this disclosure. For example, while the embodiments described above refer to particular features, the scope of this disclosure also includes embodiments having different combinations of features and embodiments that do not include all of the described features. Accordingly, the scope of the present disclosure is intended to include all such alternatives, modifications, and variations as falling within the scope of the claims, together with all equivalents thereof.

1. An apparatus comprising:
an enclosure with a first data storage section, a second data storage section, a first cooling section positioned therebetween, and a second cooling section, the second cooling section including fan modules positioned therein; and
an air-to-liquid heat exchanger including a tube and a plurality of fins thermally coupled to the tube, the air-to-liquid heat exchanger positioned in the first cooling section and configured to cool air as it passes through the air-to-liquid heat exchanger between the fins.

2. The apparatus of claim 1, further comprising:
data storage devices positioned within the first data storage section and the second data storage section.

3. The apparatus of claim 1, wherein the air-to-liquid heat exchanger is a double-pass heat exchanger.

4. The apparatus of claim 1, wherein the air-to-liquid heat exchanger is a single-pass heat exchanger.

5. (canceled)

6. The apparatus of claim 1, wherein the plurality of fins extends lengthwise along a longitudinal axis of the enclosure.

7. The apparatus of claim 1, wherein the enclosure includes a plurality of walls, wherein an input and an output to the air-to-liquid heat exchanger is positioned on the same wall of the enclosure.

8. The apparatus of claim 1, wherein the air-to-liquid heat exchanger extends partially between a first side wall and a second side wall of the enclosure, wherein a gap is positioned between the air-to-liquid heat exchanger and one of the first and the second side walls.

9. The apparatus of claim 1, further comprising:
a pump in fluid communication with the air-to-liquid heat exchanger.

10. The apparatus of claim 1, wherein the enclosure extends along a longitudinal axis, wherein air is directed along the longitudinal axis, wherein the air-to-liquid heat exchanger is arranged such that water flows through the air-to-liquid heat exchanger in a direction substantially perpendicular to the longitudinal axis.

11. The apparatus of claim 10, wherein the air-to-liquid heat exchanger is oriented such that air can pass through the air-to-liquid heat exchanger along the longitudinal axis.

12. The apparatus of claim 1, wherein the fan modules are positioned at a back end of the enclosure.

13. A system comprising:
a data storage system including a first data storage section, a second data storage section, a first cooling section positioned therebetween, and fan modules positioned within a second cooling section; and
a cooling system including a pump, a fluid source, and a heat exchanger fluidly coupled to each other,
the heat exchanger is positioned within the first cooling section and arranged to cool air as the air passes through the heat exchanger and is directed towards the fan modules,
the fluid source positioned external to the data storage system.

14. The system of claim 13, further comprising:
hard disk drives or solid state drives positioned within the first data storage section and the second data storage section.

15. The system of claim 13, wherein the heat exchanger cools air passing through the heat exchanger by 2-20 degrees Celsius.

16. The system of claim 15, further comprising:
a plurality of enclosures housing the first and second data storage sections and the first and second cooling sections, each enclosure with the fan modules and heat exchanger positioned therein.

17. The system of claim 15, further comprising:
a fluid sink positioned external to the data storage system and fluidly coupled to the pump and the heat exchanger.

18. A method for cooling electronic components positioned in an enclosure with a first data section, a second data section, a first cooling section positioned therebetween, and a second cooling section, the method comprising:
powering fan modules positioned in the second cooling section to draw air across the first data section, the first cooling section, and the second data section; and
pumping liquid through a tube of a heat exchanger, which includes a plurality of fins thermally coupled to the tube and which is positioned within the first cooling section, such that air passing through the heat exchanger between the plurality of fins is cooled to cool the second data section.

19. The method of claim 18, wherein the electronic components are data storage devices or data processing units.

20. (canceled)

21. The method of claim 18, wherein the liquid enters the enclosure at a first temperature and exits the enclosure at a second temperature that is greater than the first temperature.
